(19) United States
(12) Patent Application Publication
(10) Pub. No.: US 2023/0229826 A1
(43) Pub. Date: Jul. 20, 2023

(54) METHOD FOR ASSIGNING A LANE RELATIONSHIP BETWEEN AN AUTONOMOUS VEHICLE AND OTHER ACTORS NEAR AN INTERSECTION

(71) Applicant: Argo Al, LLC, Pittsburgh, PA (US)

(72) Inventors: Xing Sun, San Francisco, CA (US); David Breeden, Belmont, CA (US)

(21) Appl. No.: 17/648,036

(22) Filed: Jan. 14, 2022

(51) Int. Cl. G06F 30/20; G07C 5/02

(52) U.S. Cl. CPC G06F 30/20; G07C 5/02

(57) ABSTRACT

Disclosed herein are system, method, and computer program product embodiments for assigning a lane relationship between an autonomous vehicle and other actors near an intersection. For example, the method includes executing a simulation scenario that includes features of a scene through which a vehicle may travel, the simulation scenario including one or more actors. The method further includes identifying an intersection between a first road and a second road in the simulation scenario, wherein the intersection is in a planned path of the vehicle. In response to one of the actors occupying a lane of either the first road or the second road, the method includes classifying the interaction between the vehicle and the actor based on the intersection, the path of the vehicle, and the lane occupied by the actor.

### BACKGROUND

Many vehicles today, including but not limited to autonomous vehicles (AVs), use motion planning systems to decide, or help the driver make decisions about, where and how to move in an environment. Motion planning systems rely on artificial intelligence models to analyze moving actors that the vehicle sensors may perceive, make predictions about what those actors may do, and select or recommend a course of action for the vehicle that takes the actor's likely action into account.

To make predictions and determine courses of action, the vehicle's motion planning model must be trained on data that the vehicle may encounter in an environment. The more unique scenarios that are used to train a vehicle's motion planning model, the better that the model can be at making motion planning decisions. However, the range of possible scenarios that a vehicle may encounter is limitless. Manual development of a large number unique simulation scenarios would require a significant investment in time and manpower, as well as a continued cost to update individual scenarios as the motion planning model improves and vehicle behavior changes.

While systems are available to randomly develop simulation scenarios, the number of possible random scenarios is also limitless. Purely random simulation would require the motion planning model to consider an extremely large number of events that may not be relevant, or which at least would be extremely unlikely, in the real world, resulting in inefficient use of limited computing resources and time. In addition, it can require the vehicle to be trained on a large number of less relevant scenarios well before the random process yields more relevant scenarios. Therefore, methods of identifying and developing an effective set of relevant simulation scenarios, and training the vehicle's model on such scenarios, are needed.

This document describes methods and systems that address issues such as those discussed above, and/or other issues.

### SUMMARY

In a first set of embodiments, a method of classifying interactions in a simulation scenario is disclosed. The method may be embodied in computer programming instructions and/or implemented by a system that includes a processor. The method includes executing a simulation scenario that includes features of a scene through which a vehicle may travel, the simulation scenario including one or more actors. The method further includes identifying an intersection between a first road and a second road in the simulation scenario, wherein the intersection is in a planned path of the vehicle. In response to one of the actors occupying a lane of either the first road or the second road, the method includes classifying the interaction between the vehicle and the actor into one or more classifications based on the intersection, the path of the vehicle, and the lane occupied by the actor.

Implementations of the disclosure may include one or more of the following optional features. In some examples, the one or more classifications include (i) moving in the same direction, (ii) moving in opposing directions, (iii) actor crossing from the left, or (iv) actor crossing from the right. The method may include executing multiple additional simulation scenarios from a data store. For each simulation scenario, the method may include classifying one or more interactions between the vehicle and one or more actors and ranking the simulation scenarios based on the one or more classifications. In some examples, classifying the interaction includes, in response to the vehicle entering the intersection from a first lane segment of the first road and one of the actors entering the intersection from a second lane segment of the second road, classifying the interaction based on the planned path of the vehicle and a direction of the second lane segment. In some examples, classifying the interaction includes, in response to one of the actors leaving the intersection on an exit lane segment, classifying the interaction based on the planned path of the vehicle and a direction of the exit lane segment. The method may further include classifying multiple interactions between the vehicle and the one or more actors in the simulation scenario, wherein each classification includes one or more corresponding timestamps, and storing the classifications and the corresponding timestamps in a data store associated with the simulation scenario. In some examples, the simulation scenario includes semantic information and the classification is based on direction-change semantics of one or more lane segments occupied by the vehicle or the actor in the intersection.

In other embodiments, a system includes a processor, a data store of simulation scenarios, and a non-transient memory that stores programming instructions configured to cause the processor to execute a simulation scenario that includes features of a scene through which a vehicle may travel, the simulation scenario including one or more actors. The programming instructions further cause the processor to identify an intersection between a first road and a second road in the simulation scenario, wherein the intersection is in a planned path of the vehicle. In response to one of the actors occupying a lane of either the first road or the second road, programming instructions further cause the processor to the classify the interaction between the vehicle and the actor into one or more classifications based on the intersection, the path of the vehicle, and the lane occupied by the actor.

Implementations of the disclosure may include one or more of the following optional features. In some examples, the one or more classifications include (i) moving in the same direction, (ii) moving in opposing directions, (iii) actor crossing from the left, or (iv) actor crossing from the right. The programming instructions may be further configured to cause the processor to execute multiple additional simulation scenarios from the data store. For each simulation scenario, the programming instructions may cause the processor to classify one or more interactions between the vehicle and one or more actors and rank the simulation scenarios based on the one or more classifications. The programming instructions may include programming instructions configured to cause the processor to, in response to the vehicle entering the intersection from a first lane segment of the first road and one of the actors entering the intersection from a second lane segment of the second road, classify the interaction based on the planned path of the vehicle and a direction of the second lane segment. The programming instructions may include programming instructions configured to cause the processor to, in response to one of the actors leaving the intersection on an exit lane segment, classify the interaction based on the planned path of the vehicle and a direction of the exit lane segment. The programming instructions may be further configured to cause the processor to classify multiple interactions between the vehicle and the one or more actors in the simulation scenario, wherein each classification includes one or more corresponding timestamps, and store the classifications and the corresponding timestamps in a data store associated with the simulation scenario. In some examples, the simulation scenario includes semantic information and the classification is based on direction-change semantics of one or more lane segments occupied by the vehicle or the actor in the intersection.

In other embodiments, a computer program product is disclosed. The product includes a memory that stores programming instructions configured to cause a processor to classify interactions in a simulation scenario by executing a simulation scenario that includes features of a scene through which a vehicle may travel. The programming instructions further cause the processor to identify an intersection between a first road and a second road in the simulation scenario, wherein the intersection is in a planned path of the vehicle. In response to one of the actors occupying a lane of either the first road or the second road, programming instructions further cause the processor to the classify the interaction between the vehicle and the actor into one or more classifications based on the intersection, the path of the vehicle, and the lane occupied by the actor.

Implementations of the disclosure may include one or more of the following optional features. In some examples, the one or more classifications include (i) moving in the same direction, (ii) moving in opposing directions, (iii) actor crossing from the left, or (iv) actor crossing from the right. The programming instructions may be further configured to cause the processor to execute multiple additional simulation scenarios from the data store. For each simulation scenario, the programming instructions may cause the processor to classify one or more interactions between the vehicle and one or more actors and rank the simulation scenarios based on the one or more classifications. The programming instructions may include programming instructions configured to cause the processor to, in response to the vehicle entering the intersection from a first lane segment of the first road and one of the actors entering the intersection from a second lane segment of the second road, classify the interaction based on the planned path of the vehicle and a direction of the second lane segment. The programming instructions may include programming instructions configured to cause the processor to, in response to one of the actors leaving the intersection on an exit lane segment, classify the interaction based on the planned path of the vehicle and a direction of the exit lane segment. The programming instructions may be further configured to cause the processor to classify multiple interactions between the vehicle and the one or more actors in the simulation scenario, wherein each classification includes one or more corresponding timestamps, and store the classifications and the corresponding timestamps in a data store associated with the simulation scenario. In some examples, the simulation scenario includes semantic information and the classification is based on direction-change semantics of one or more lane segments occupied by the vehicle or the actor in the intersection.

### BRIEF DESCRIPTION OF THE DRAWINGS

The accompanying drawings are incorporated herein and form a part of the specification.

FIG. 1 illustrates an example autonomous vehicle system, in accordance with aspects of the disclosure.

FIG. 2 illustrates an example architecture for a vehicle, in accordance with aspects of the disclosure.

FIG. 3 shows a high-level overview of subsystems of an AV stack.

FIG. 4 illustrates a map of roadways.

FIG. 5 illustrates an example four-way intersection.

FIG. 6 illustrates example interactions.

FIG. 7 shows an example method for classifying interactions.

FIGS. 8A-8D show example interactions.

FIG. 9 shows a flowchart of an example classification method.

FIGS. 10A and 10B show example interactions.

FIG. 11 is an example computer system useful for implementing various embodiments.

In the drawings, like reference numbers generally indicate identical or similar elements. Additionally, generally, the left-most digit(s) of a reference number identifies the drawing in which the reference number first appears.

### DETAILED DESCRIPTION

Provided herein are system, apparatus, device, method and/or computer program product embodiments, and/or combinations and sub-combinations thereof, for a method for assigning a lane relationship between an Autonomous Vehicle (AV) and other actors near an intersection. The assigned lane relationship may be used to characterize the interaction between the AV and other actors at the intersection. The characterization may assist in selecting a relevant set of simulation scenarios for training the AV's motion planning model. For example, scenarios having with little or no interaction between the AV and the actor may be deemphasized in favor of scenarios having greater interaction between the AV and the actor. Furthermore, the simulation scenarios may be selected and curated into a set of scenarios including a comprehensive variety of interactions between the AV and the actor. These interactions may include the actor crossing the path of the AV from either the left side or the right side of the direction of travel of the AV and may include a variety of intersection configurations, including 3-way, 4-way, 5-way and more complex intersection configurations.

The term “vehicle” refers to any moving form of conveyance that is capable of carrying either one or more human occupants and/or cargo and is powered by any form of energy. The term “vehicle” includes, but is not limited to, cars, trucks, vans, trains, autonomous vehicles, aircraft, aerial drones and the like. An AV is a vehicle having a processor, programming instructions and drivetrain components that are controllable by the processor without requiring a human operator. An autonomous vehicle may be fully autonomous in that it does not require a human operator for most or all driving conditions and functions, or it may be semi-autonomous in that a human operator may be required in certain conditions or for certain operations, or that a human operator may override the vehicle's autonomous system and may take control of the vehicle.

An AV software stack includes various software platforms which handle various tasks that help the AV move throughout an environment. These tasks include tasks such as perception, motion planning, and motion control. An AV stack may reside in a software repository (in the physical form of computer-readable memory) that is available to a vehicle's original equipment manufacturer (OEM) and/or to an OEM's suppliers. An AV stack also may be directly deployed on a vehicle. To be effective, before it is deployed on a vehicle an AV stack must be trained on multiple simulation scenarios. Training is a process that applies a simulation scenario definition to one or more of the AV stack's systems so that the AV stack can process the simulation scenario and generate a response. Supplemental training also may be done after an AV stack is deployed on a vehicle, with additional simulation scenarios that will continue to improve the AV stack's operation and help the AV recognize and react to an increased variety of conditions when it encounters them in the real world. By training the AV's motion planning model on a rich and diverse variety of relevant scenarios, the model can be more effectively trained to make appropriate planning decisions.

Notably, the present solution is being described herein in the context of an autonomous vehicle. However, the present solution is not limited to autonomous vehicle applications. The present solution may be used in other applications such as robotic applications, radar system applications, metric applications, and/or system performance applications.

As used in this document, the singular forms “a,” “an,” and “the” include plural references unless the context clearly dictates otherwise. Unless defined otherwise, all technical and scientific terms used herein have the same meanings as commonly understood by one of ordinary skill in the art. As used in this document, the term “comprising” means “including, but not limited to.” Definitions for additional terms that are relevant to this document are included at the end of this Detailed Description.

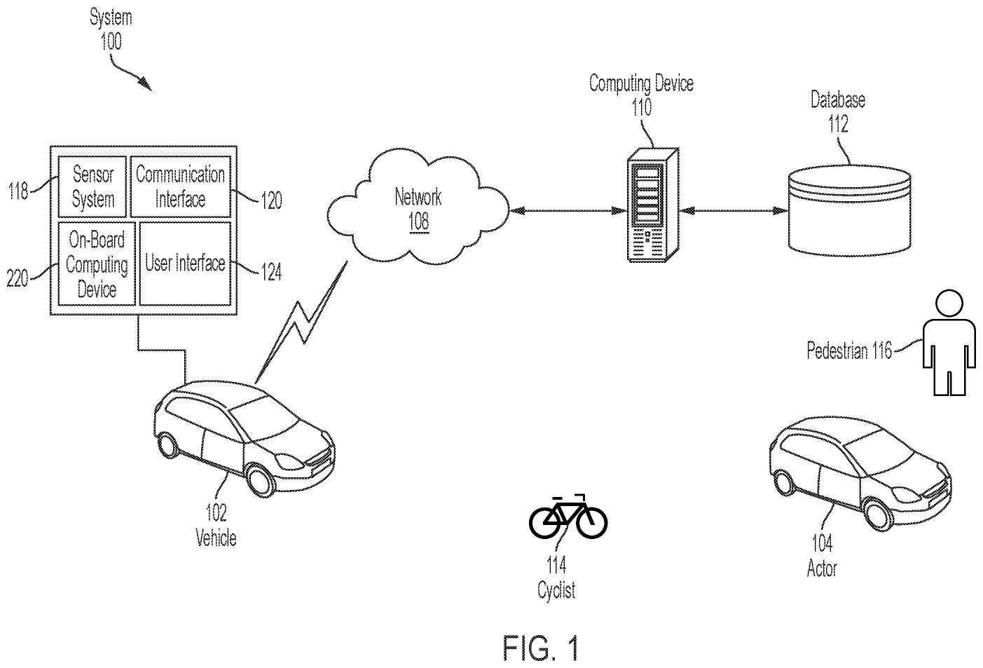

FIG. 1 illustrates an example autonomous vehicle system 100, in accordance with aspects of the disclosure. System 100 comprises a vehicle 102 that is traveling on a path along a road in a semi-autonomous or autonomous manner. Vehicle 102 is also referred to herein as AV 102. AV 102 can include, but is not limited to, a land vehicle (as shown in FIG. 1), an aircraft, or a watercraft.

AV 102 is generally configured to detect objects or actors 104, 114, 116 in proximity thereto. The actors can include, but are not limited to, another vehicle 104, a cyclist 114 (such as a rider of a bicycle, electric scooter, motorcycle, or the like) and/or a pedestrian 116.

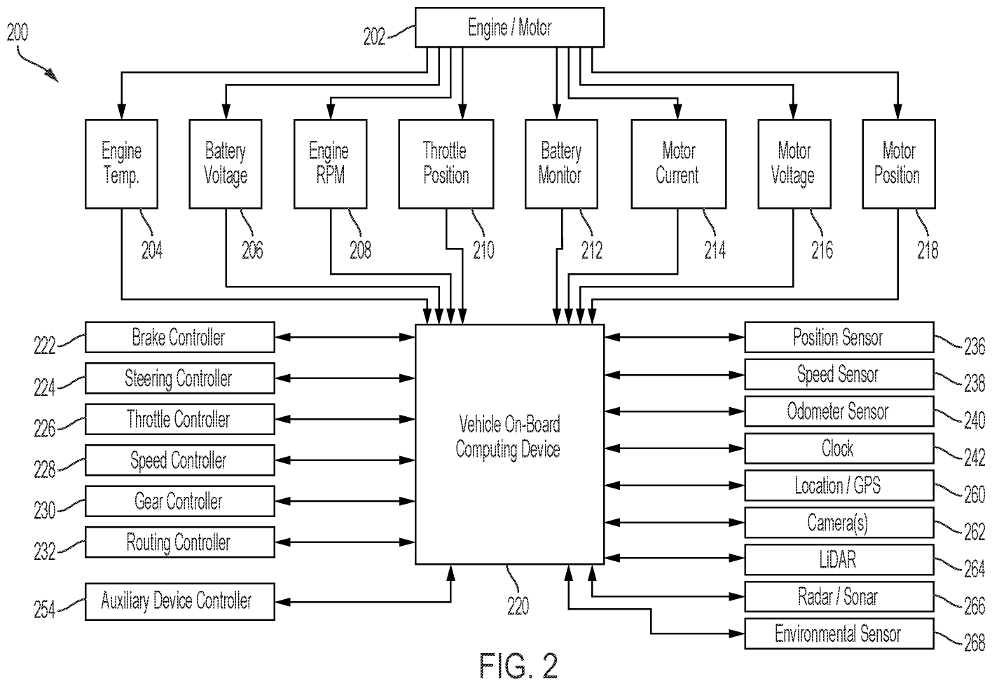

As illustrated in FIG. 1, the AV 102 may include a sensor system 118, an on-board computing device 220 (FIG. 2), a communications interface 120, and a user interface 124. Autonomous vehicle 102 may further include certain components (as illustrated, for example, in FIG. 2) included in vehicles, which may be controlled by the on-board computing device 220 using a variety of communication signals and/or commands, such as, for example, acceleration signals or commands, deceleration signals or commands, steering signals or commands, braking signals or commands, etc.

The sensor system 118 may include one or more sensors that are coupled to and/or are included within the AV 102, as illustrated in FIG. 2. For example, such sensors may include, without limitation, a LiDAR system, a radio detection and ranging (RADAR) system, a laser detection and ranging (LADAR) system, a sound navigation and ranging (SONAR) system, one or more cameras (e.g., visible spectrum cameras, infrared cameras, etc.), temperature sensors, position sensors (e.g., global positioning system (GPS), etc.), location sensors, fuel sensors, motion sensors (e.g., inertial measurement units (IMU), etc.), humidity sensors, occupancy sensors, or the like. The sensor data can include information that describes the location of objects within the surrounding environment of the AV 102, information about the environment itself, information about the motion of the AV 102, information about a route of the vehicle, or the like. As AV 102 travels over a surface, at least some of the sensors may collect data pertaining to the surface.

The AV 102 may also communicate sensor data collected by the sensor system to a remote computing device 110 (for example, a cloud processing system) over communications network 108. Remote computing device 110 may be configured with one or more servers to process one or more processes of the technology described in this document. Remote computing device 110 may also be configured to communicate data/instructions to/from AV 102 over network 108, to/from server(s) and/or database(s) 112.

Network 108 may include one or more wired or wireless networks. For example, the network 108 may include a cellular network (e.g., a long-term evolution (LTE) network, a code division multiple access (CDMA) network, a 3G network, a 4G network, a 5G network, another type of next generation network, etc.). The network may also include a public land mobile network (PLMN), a local area network (LAN), a wide area network (WAN), a metropolitan area network (MAN), a telephone network (e.g., the Public Switched Telephone Network (PSTN)), a private network, an ad hoc network, an intranet, the Internet, a fiber optic-based network, a cloud computing network, and/or the like, and/or a combination of these or other types of networks.

AV 102 may retrieve, receive, display, and edit information generated from a local application or delivered via network 108 from database 112. Database 112 may be configured to store and supply raw data, indexed data, structured data, map data, program instructions or other configurations as is known.

The communications interface 120 may be configured to allow communication between AV 102 and external systems, such as, for example, external devices, sensors, other vehicles, servers, data stores, databases etc. The communications interface 120 may utilize any now or hereafter known protocols, protection schemes, encodings, formats, packaging, etc. such as, without limitation, Wi-Fi, an infrared link, Bluetooth, etc. The user interface system 124 may be part of peripheral devices implemented within the AV 102 including, for example, a keyboard, a touch screen display device, a microphone, and a speaker, etc.

FIG. 2 illustrates an example system architecture 200 for a vehicle, in accordance with aspects of the disclosure. Vehicles 102 and/or 104 of FIG. 1 can have the same or similar system architecture as that shown in FIG. 2. Thus, the following discussion of system architecture 200 is sufficient for understanding vehicle(s) 102, 104 of FIG. 1. However, other types of vehicles are considered within the scope of the technology described herein and may contain more or less elements as described in association with FIG. 2. As a non-limiting example, an airborne vehicle may exclude brake or gear controllers, but may include an altitude sensor. In another non-limiting example, a water-based vehicle may include a depth sensor. One skilled in the art will appreciate that other propulsion systems, sensors and controllers may be included based on a type of vehicle, as is known.

As shown in FIG. 2, system architecture 200 includes an engine or motor 202 and various sensors 204-218 for measuring various parameters of the vehicle. In gas-powered or hybrid vehicles having a fuel-powered engine, the sensors may include, for example, an engine temperature sensor 204, a battery voltage sensor 206, an engine Rotations Per Minute (“RPM”) sensor 208, and a throttle position sensor 210. If the vehicle is an electric or hybrid vehicle, then the vehicle may have an electric motor, and accordingly includes sensors such as a battery monitoring system 212 (to measure current, voltage and/or temperature of the battery), motor current 214 and voltage 216 sensors, and motor position sensors 218 such as resolvers and encoders.

Operational parameter sensors that are common to both types of vehicles include, for example: a position sensor 236 such as an accelerometer, gyroscope and/or inertial measurement unit; a speed sensor 238; and an odometer sensor 240. The vehicle also may have a clock 242 that the system uses to determine vehicle time during operation. The clock 242 may be encoded into the vehicle on-board computing device, it may be a separate device, or multiple clocks may be available.

The vehicle also includes various sensors that operate to gather information about the environment in which the vehicle is traveling. These sensors may include, for example: a location sensor 260 (e.g., a Global Positioning System (“GPS”) device); object detection sensors such as one or more cameras 262; a lidar system 264; and/or a radar and/or a sonar system 266. The sensors also may include environmental sensors 268 such as a precipitation sensor and/or ambient temperature sensor. The object detection sensors may enable the vehicle to detect objects that are within a given distance range of the vehicle 200 in any direction, while the environmental sensors collect data about environmental conditions within the vehicle's area of travel.

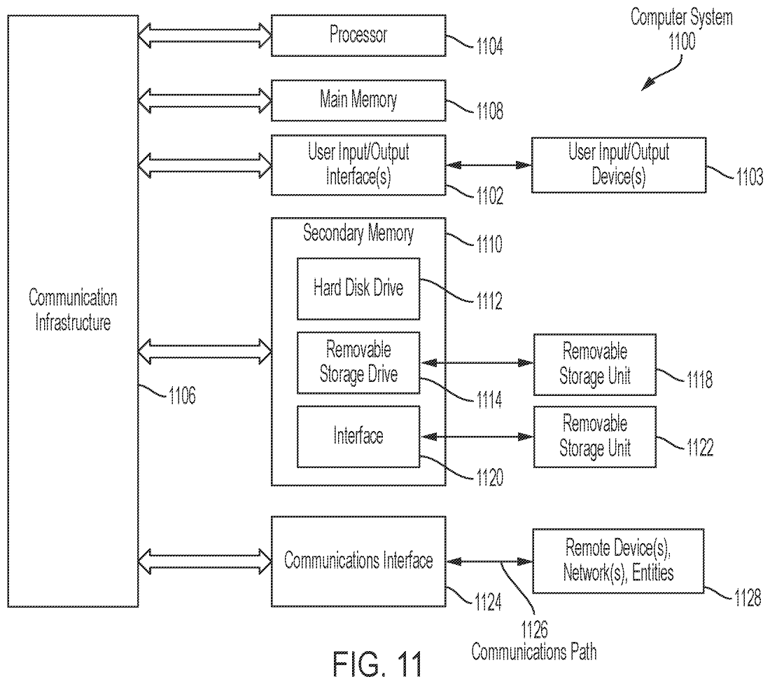

During operations, information is communicated from the sensors to a vehicle on-board computing device 220. The on-board computing device 220 may be implemented using the computer system of FIG. 11. The vehicle on-board computing device 220 analyzes the data captured by the sensors and optionally controls operations of the vehicle based on results of the analysis. For example, the vehicle on-board computing device 220 may control: braking via a brake controller 222; direction via a steering controller 224; speed and acceleration via a throttle controller 226 (in a gas-powered vehicle) or a motor speed controller 228 (such as a current level controller in an electric vehicle); a differential gear controller 230 (in vehicles with transmissions); and/or other controllers. Auxiliary device controller 254 may be configured to control one or more auxiliary devices, such as testing systems, auxiliary sensors, mobile devices transported by the vehicle, etc.

Geographic location information may be communicated from the location sensor 260 to the on-board computing device 220, which may then access a map of the environment that corresponds to the location information to determine known fixed features of the environment such as streets, buildings, stop signs and/or stop/go signals. The map may include geometric relationships between features of the environment. Captured images from the cameras 262 and/or object detection information captured from sensors such as lidar system 264 is communicated from those sensors) to the on-board computing device 220. The object detection information and/or captured images are processed by the on-board computing device 220 to detect objects in proximity to the vehicle 200. Any known or to be known technique for making an object detection based on sensor data and/or captured images can be used in the embodiments disclosed in this document.

The on-board computing device 220 may include and/or may be in communication with a routing controller 232 that generates a navigation route from a start position to a destination position for an autonomous vehicle. The routing controller 232 may access a map data store to identify possible routes and road segments that a vehicle can travel on to get from the start position to the destination position. The routing controller 232 may score the possible routes and identify a preferred route to reach the destination. For example, the routing controller 232 may generate a navigation route that minimizes Euclidean distance traveled or other cost function during the route, and may further access the traffic information and/or estimates that can affect an amount of time it will take to travel on a particular route. Depending on implementation, the routing controller 232 may generate one or more routes using various routing methods, such as Dijkstra's algorithm, Bellman-Ford algorithm, or other algorithms. The routing controller 232 may also use the traffic information to generate a navigation route that reflects expected conditions of the route (e.g., current day of the week or current time of day, etc.), such that a route generated for travel during rush-hour may differ from a route generated for travel late at night. The routing controller 232 may also generate more than one navigation route to a destination and send more than one of these navigation routes to a user for selection by the user from among various possible routes.

In various embodiments, the on-board computing device 220 may determine perception information of the surrounding environment of the AV 102. Based on the sensor data provided by one or more sensors and location information that is obtained, the on-board computing device 220 may determine perception information of the surrounding environment of the AV 102. The perception information may represent what an ordinary driver would perceive in the surrounding environment of a vehicle. The perception data may include information relating to one or more objects in the environment of the AV 102. For example, the on-board computing device 220 may process sensor data (e.g., LiDAR or RADAR data, camera images, etc.) in order to identify objects and/or features in the environment of AV 102. The objects may include traffic signals, roadway boundaries, other vehicles, pedestrians, and/or obstacles, etc. The on-board computing device 220 may use any now or hereafter known object recognition algorithms, video tracking algorithms, and computer vision algorithms (e.g., track objects frame-to-frame iteratively over a number of time periods) to determine the perception.

In some embodiments, the on-board computing device 220 may also determine, for one or more identified objects in the environment, the current state of the object. The state information may include, without limitation, for each object: current location; current speed and/or acceleration, current heading; current pose; current shape, size, or footprint; type (e.g., vehicle vs. pedestrian vs. bicycle vs. static object or obstacle); and/or other state information.

The on-board computing device 220 may perform one or more prediction and/or forecasting operations. For example, the on-board computing device 220 may predict future locations, trajectories, and/or actions of one or more objects. For example, the on-board computing device 220 may predict the future locations, trajectories, and/or actions of the objects based at least in part on perception information (e.g., the state data for each object comprising an estimated shape and pose determined as discussed below), location information, sensor data, and/or any other data that describes the past and/or current state of the objects, the AV 102, the surrounding environment, and/or their relationship(s). For example, if an object is a vehicle and the current driving environment includes an intersection, the on-board computing device 220 may predict whether the object will likely move straight forward or make a turn. If the perception data indicates that the intersection has no traffic light, the on-board computing device 220 may also predict whether the vehicle may have to fully stop prior to enter the intersection.

In various embodiments, the on-board computing device 220 may determine a motion plan for the autonomous vehicle. For example, the on-board computing device 220 may determine a motion plan for the autonomous vehicle based on the perception data and/or the prediction data. Specifically, given predictions about the future locations of proximate objects and other perception data, the on-board computing device 220 can determine a motion plan for the AV 102 that best navigates the autonomous vehicle relative to the objects at their future locations.

In some embodiments, the on-board computing device 220 may receive predictions and make a decision regarding how to handle objects and/or actors in the environment of the AV 102. For example, for a particular actor (e.g., a vehicle with a given speed, direction, turning angle, etc.), the on-board computing device 220 decides whether to overtake, yield, stop, and/or pass based on, for example, traffic conditions, map data, state of the autonomous vehicle, etc. Furthermore, the on-board computing device 220 also plans a path for the AV 102 to travel on a given route, as well as driving parameters (e.g., distance, speed, and/or turning angle). That is, for a given object, the on-board computing device 220 decides what to do with the object and determines how to do it. For example, for a given object, the on-board computing device 220 may decide to pass the object and may determine whether to pass on the left side or right side of the object (including motion parameters such as speed). The on-board computing device 220 may also assess the risk of a collision between a detected object and the AV 102. If the risk exceeds an acceptable threshold, it may determine whether the collision can be avoided if the autonomous vehicle follows a defined vehicle trajectory and/or implements one or more dynamically generated emergency maneuvers is performed in a pre-defined time period (e.g., N milliseconds). If the collision can be avoided, then the on-board computing device 220 may execute one or more control instructions to perform a cautious maneuver (e.g., mildly slow down, accelerate, change lane, or swerve). In contrast, if the collision cannot be avoided, then the on-board computing device 220 may execute one or more control instructions for execution of an emergency maneuver (e.g., brake and/or change direction of travel).

As discussed above, planning and control data regarding the movement of the autonomous vehicle is generated for execution. The on-board computing device 220 may, for example, control braking via a brake controller; direction via a steering controller; speed and acceleration via a throttle controller (in a gas-powered vehicle) or a motor speed controller (such as a current level controller in an electric vehicle); a differential gear controller (in vehicles with transmissions); and/or other controllers.

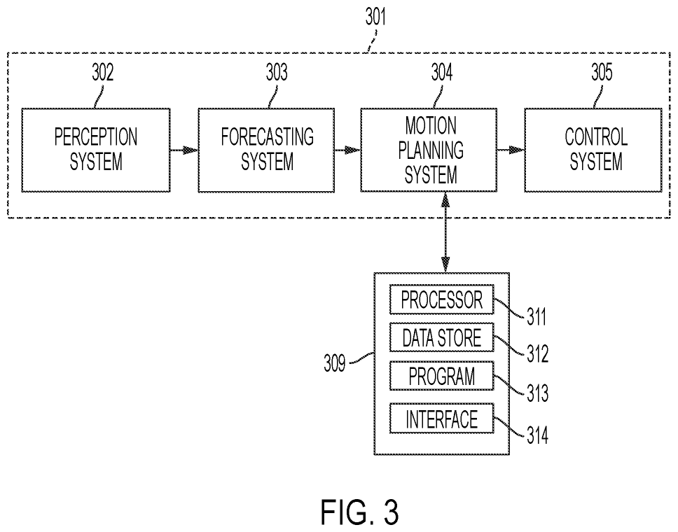

FIG. 3 shows a high-level overview of subsystems of an AV stack that may be relevant to the discussion below. Certain components of the subsystems may be embodied in processor hardware and computer-readable programming instructions that are part of a computing system 301 that is either onboard the vehicle or that is offboard and stored on one or more memory devices. The subsystems may include a perception system 302 that includes sensors that capture information about moving actors and other objects that exist in the vehicle's immediate surroundings. Example sensors include cameras, LiDAR sensors and radar sensors. The data captured by such sensors (such as digital images, LiDAR point cloud data, or radar data) is known as perception data. The perception data may include data representative of one or more objects in the environment.

The perception system may include one or more processors and computer-readable memory with programming instructions and/or trained artificial intelligence models that, during a run of the AV, will process the perception data to identify objects and assign categorical labels and unique identifiers to each object detected in a scene. Categorical labels may include categories such as vehicle, bicyclist, pedestrian, building, and the like. Methods of identifying objects and assigning categorical labels to objects are well known in the art, and any suitable classification process may be used, such as those that make bounding box predictions for detected objects in a scene and use convolutional neural networks or other computer vision models. Some such processes are described in Yurtsever et al., “A Survey of Autonomous Driving: Common Practices and Emerging Technologies” (published in IEEE Access, April 2020).

The vehicle's perception system 302 may deliver perception data to the vehicle's forecasting system 303. The forecasting system (which also may be referred to as a prediction system) will include processors and computer-readable programming instructions that are configured to process data received from the perception system and forecast actions of other actors that the perception system detects.

The vehicle's perception system 302, as well as the vehicle's forecasting system 303, will deliver data and information to the vehicle's motion planning system 304 and motion control system 305 so that the receiving systems may assess such data and initiate any number of reactive motions to such data. The motion planning system 304 and motion control system 305 include and/or share one or more processors and computer-readable programming instructions that are configured to process data received from the other systems, compute a trajectory for the vehicle, and output commands to vehicle hardware to move the vehicle according to the determined trajectory. Example actions that such commands may cause include causing the vehicle's brake control system to actuate, causing the vehicle's acceleration control subsystem to increase speed of the vehicle, or causing the vehicle's steering control subsystem to turn the vehicle. Various motion planning techniques are well known, for example as described in Gonzalez et al., “A Review of Motion Planning Techniques for Automated Vehicles,” published in IEEE Transactions on Intelligent Transportation Systems, vol. 17, no. 4 (April 2016).

The subsystems described above may be implemented as components of an AV stack, which may be trained on various simulation scenarios. As described above, the system 301 on which the subsystems may be installed may be a vehicle's computer processing hardware, or it may be one or more memory devices that are offboard the vehicle. In addition, in the present embodiments, the system 301 on which the AV stack is installed will be in electronic communication with a training system 309. The training system 309 will include a processor 311, a data store 312 containing a variety of stored simulation scenarios, and a memory containing programming instructions 313 for generating, modifying and using simulation scenarios to train the system 301.

Optionally, the training system 309 also may include a user interface 314 for presenting information to a user and receiving information and/or commands from the user. For example, the user interface 314 may include a display via which the system may output graphic illustrations of simulation scenarios, as well as one or more menus or forms that present features or options for augmenting the scenario. The user interface also may include an input device such as a mouse, keyboard, keypad, microphone and/or touch-screen elements of the display via which the issuer may select variations for a displayed scenario. The variations may include new actors, configuration parameters for new or existing actors, or other information.

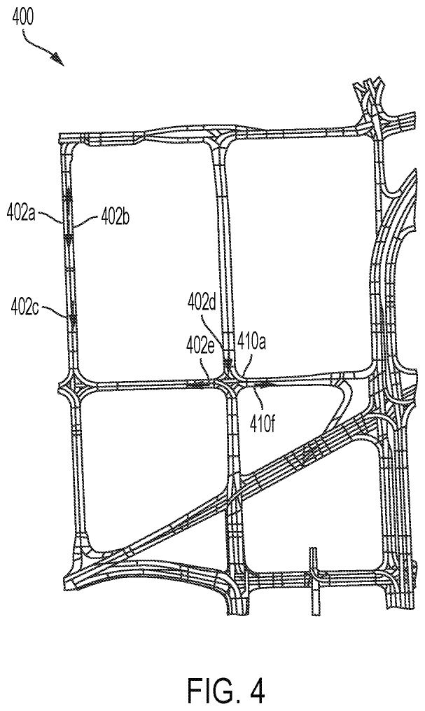

As described above, the AV may access a map of the environment in which it is operating including geometric relationships between features of the environment, and/or route or path information. The route or path information may include roadways in the scene and may include semantic information related to the roadways. FIG. 4 illustrates a map 400 of roadways including geometric and semantic information. The map 400 indicates geometrical relationships between roads sufficient for the routing of the on-board computing device 220 to plan a path for the AV 102 to travel on to reach a destination. The map 400 indicates semantic information, as well. The semantic information may include a directed graph of lane segments 402, interconnected with successor and predecessor lane segments 402 (e.g., in the direction of travel of the vehicle, such as AV 102, occupying the lane segment 402). The semantic information may also include intersections 410 where multiple lane segments meet. A vehicle, such as AV 102, entering an intersection 410 from a lane segment 402, may exit the intersection 410 using one of multiple possible lane segments 402. As shown, each road in the map 400 includes a number of neighboring lane segments (e.g., 402a, 402b), each lane segment 402 having properties, including a direction of travel.

FIG. 4 illustrates the sematic information of a subset of the lane segments 402 and intersections 410 of the map 400 of roadways. Here, neighboring lane segments 402a and 402b are lanes of a two-way road in a right-hand traffic system (a traffic system where the driver is positioned on the left side of the vehicle). Therefore, lane segments 402a and 402b have opposite directions of travel. Roads may also include lane segments 402 having the same direction of travel, e.g., multi-lane divided highways or motorways. Here, lane segment 402a has a successor (lane segment 402c) in the direction of travel. A vehicle traveling on lane segment 402a proceeds in the direction of travel onto lane segment 402c. Lane segment 402d has a successor intersection 410a in the direction of travel. A vehicle traveling on lane segment 402d proceeds into intersection 410a in the direction of travel. A vehicle entering intersection 410a from lane segment 402d may exit intersection 410a using one of a multiple of lane segments (e.g., 402e, 402f), e.g. by changing direction in the intersection 410a or by proceeding through the intersection 410a. Thus, a vehicle may proceed from a lane segment 402d having a first direction, through the intersection 410a, onto a lane segment (e.g., 402e, 402f) having a different direction. The map 400 may indicate additional semantic information beyond what is explicitly illustrated in FIG. 4.

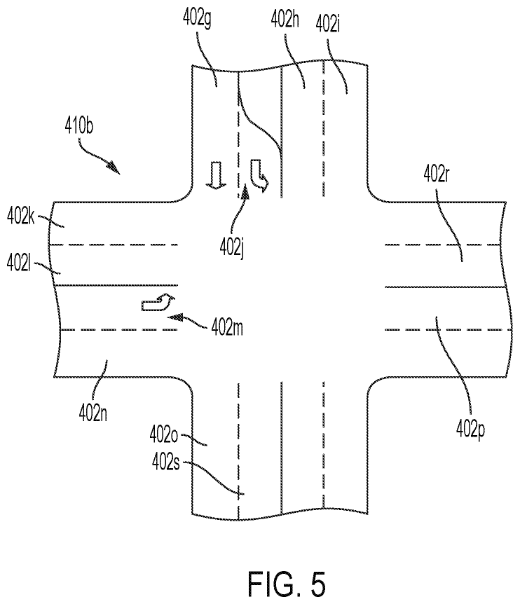

FIG. 5 illustrates an example four-way intersection 410b. That is, four roads meet at the intersection 410b, each of the roads including one or more lane segments 402. Actors 104 may enter the intersection 410 from a lane segment 402 of any of the four roads and may exit onto a lane segment of any of the other roads after passing through a portion of the intersection 410b. Other intersection 410 configurations as possible, including three-way intersections, such as T-shaped intersections, where three roads meet. Traffic circles or roundabouts may be represented in the map 400 as a series of three-way intersections in close proximity to one another. In some examples, five or more roads meet at an intersection 410. At the intersection 410b of FIG. 5, lane segments (e.g., 402j, 402m) may include direction-change semantics, e.g., a “left-turn lane,” “right-turn lane,” “go straight lane,” and/or yield semantics. Here, lane 402j is a left-turn lane segment, meaning that vehicles in lane segment 402j will turn left at the intersection, exiting the intersection using, e.g. lane segment 402p. Similarly, lane 402n is a right-turn lane segment, meaning that vehicles in lane segment 402j will turn right at the intersection, exiting the intersection using, e.g. lane segment 402o. As shown, some lane segments have multiple successors. For example, lane segment 402g has two successors: lane segment 402j and the intersection 410b. A vehicle, such as AV 102, traveling on lane segment 402g may continue on lane segment 402g in order to enter intersection 410b in a lane segment 402 that does not have direction-change semantics and exit intersection 410b using lane segment 402o. Alternatively, AV 102 may follow lane segment 402g to lane segment 402j in order to enter intersection 410b in a lane segment 402j that has left-turn semantics and exit intersection 410b using, e.g., lane segment 402p. In addition to including semantic information about intersections, the map 400 may also include geometric information including geometric relationships between lanes entering and departing from intersections.

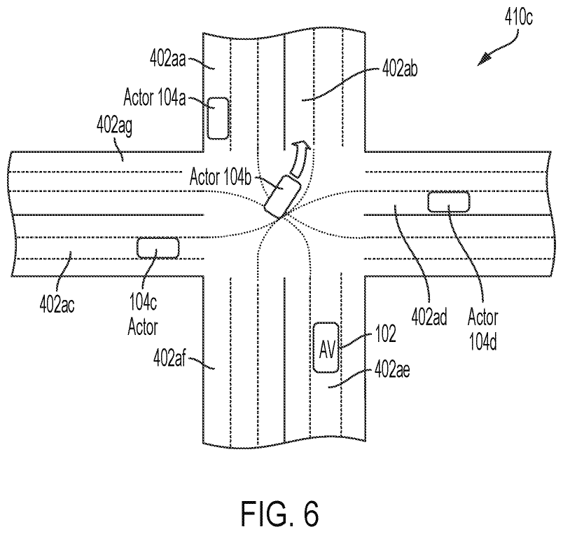

FIG. 6 shows an example intersection 410c in which an AV and a moving object might interact. The nature of the interactions may depend on the relative orientations of the lane segments 402 that the AV 102 and one or more actors 104 occupy in the intersection. As described above with respect to FIG. 1, the actors can include, but are not limited to, another vehicle 104 or, e.g., a cyclist 114 such as a rider of a bicycle, electric scooter, motorcycle, or the like (not shown). Here, the intersection is configured as a four-way intersection. That is, four roads meet at the intersection 410c. Actors (e.g., 104a, 104b, 104c, 104d) may enter the intersection from any of the four roads and may exit onto any of the other roads after passing through a portion of the intersection 410c. Each actor 104 occupies a lane segment (e.g., 402aa, 402ab, 402ac, 402ad) as described above. Each lane segment 402 may has a direction of travel and may have direction-change semantics. Each actor 104 progresses from the lane segment 402 it currently occupies to a successor lane segment 402. As described above, a lane segment 402 may have more than one successor lane segments 402. The AV 102 occupies a lane segment 402ae, which also has a direction of travel and may have direction-change semantics.

An AV training system may apply one or more simulation scenarios to the AV 102. The AV 102 may operate in the virtual environment of the simulation scenario in a similar manner to operating during a run in a real-world environment. The AV 102 may perceive real and/or virtual actors 104 and may follow a planned path through the real or virtual environment. In some examples, the AV 102 operates in a restricted real-world environment, such as an abandoned airfield. The AV 102 may perceive and interact with a variety of real and/or simulated actors 104 in the restricted environment. In some examples, the AV 102 operates in the general environment and perceives and interacts with a variety of real actors. In each of these real and simulated environments, the AV 102 may record time-stamped information, including the position and lane segment occupied by the AV 102 and by actors 104 perceived by the AV 102. The recorded data may be analyzed and/or used for subsequent simulation or training scenarios. The data may include information related to interactions between the AV 102 and actors 104 near intersections 410. For example, the recorded data may be analyzed, using any of the methods of this disclosure, to determine lane relationships between the AV 102 and actors 104 near an intersection and to classify the recorded data based on the determined lane relationship. In this way, recorded data, e.g., from fleets of AVs 102 operating on the general roadways, may be effectively curated to provide a diverse set of simulation scenarios for training other AVs 102.

As the AV 102 follows its path through the scene, the AV 102 may interact with the actors (e.g. 104a, 104b, 104c, 104d) in different ways. Here, actor 104b passes through the intersection in a lane segment having left-turn semantics, exiting on to lane segment 402ab, which has a direction which is the same as the direction as the successor lane segment to lane segment 402ae occupied by the AV 102 as AV 102 enters the intersection. Because actor 104b turned left at the intersection to exit in the same direction as AV 102, it can be deduced that actor 104b entered the intersection from a lane segment to the left of the lane segment occupied by the AV 102 as AV 102 enters the intersection. Therefore, the relative orientation of actor 104b and the AV 102 is actor 104b crossing from the left of AV 102. Actor 104a occupies a lane segment 402aa, whose successor lane segment in the intersection has a direction opposite to the direction of the successor lane segment to lane segment 402e occupied by the AV 102. And the successor to lane segment 402aa is intersection 410c. Actor 104a may enter the intersection from lane segment 402aa and exit the intersection 410ac using one of several lane segments (e.g., 410af, 410ag). For example, actor 104a may proceed straight through the intersection and exit using lane segment 402af, which has a direction opposite to the lane segment 402ae occupied by the AV 102. Alternatively, actor 104a may turn right at the intersection and exit the intersection using lane segment 402ag. Actors 104c and 104d occupy lane segments (402ac, 402ad) which have respective directions that are neither the same as nor opposite to the lane segment 402 occupied by the AV 102. However, the successor to lane segments 402ac and 402ad (occupied by actors 104c and 104d) is intersection 410c, which is also the successor to lane segment 402ae (occupied by the AV 102). Because the lane segments occupied by the AV 102 and the actor (e.g., 104c, 104d) meet at the intersection 410c, the geometric relationship between the lane segments may be determined by the map 400.

Simulation scenarios may be classified according to interactions or potential interactions between the AV 102 and other actors 104 near intersections 410 in the scene. In some examples, an actor 104 is near an intersection if the AV 102 perceives the actor 104 and the intersection 410 simultaneously, either in a simulation or in a previously recorded run of the AV 102. The actor 104 may be near an intersection if it is within, e.g., 30 meters of the intersection 410 when the AV 102 perceives the actor 104 or when the AV 102 is within, e.g., 30 meters of the intersection 410. In some examples, the classifications include (i) AV 102 and actor 104 moving in the same direction, (ii) AV 102 and actor 104 moving in opposing directions, (iii) actor 104 crossing the path of the AV 102 from the left, or (iv) actor 104 crossing the path of the AV 102 from the right. A simulation may also have no classification, e.g., if the simulation scenario does not include interactions between the AV 102 and an actor 104 near an intersection 410, or if the nature of the interaction or the relative positions of the AV 102 and the actor 104 cannot be determined. Classifying simulation scenarios in this way allows the AV training system to include a diverse set of simulation scenarios in the set of training scenarios for training the AV 102. The AV training system may prioritize or rank simulation scenarios for inclusion in a training data set based on their associated classifications. A simulation scenario may be classified according to more than one interaction or potential interaction, e.g., if the AV 102 encounters more than one actor near one or more intersections 410 along the planned path of the AV 102 in the scenario. In some examples, the simulation scenario is tagged or annotated to indicate any or all of its one or more classifications, allowing the AV training system to select a set of appropriately diverse simulation scenarios for training. Each classification may have a corresponding time stamp indicating a moment or a period in time during the simulation when the interaction occurred. In some examples, the classifications are stored in a database, where they can be retrieved by the AV training system for use in selecting simulation scenarios.

In some examples, each simulation scenario is successful or unsuccessful, e.g., based on whether the AV 102 completes a planned path or trajectory in the scenario. For example, a conflict between the AV 102 and an actor 104 detected by the AV 102 may impede or prevent the AV 102 from continuing on the trajectory, or the AV 102 may detect an unpredictable and/or novel occurrence which falls outside the parameters of the AV's programming or training, causing the AV 102 to slow or stop or be unable to continue on the planned trajectory. For example, the AV's programming or training may require the AV 102 to follow all traffic rules and/or maintain distances between the AV 102 and other objects in the scene and near the AV 102, including above the AV 102. Strict adherence to all traffic rules and/or maintaining distances between the AV 102 and other objects may also cause the AV 102 to slow or stop or be unable to continue on the planned trajectory. The AV training system may flag unsuccessful simulation scenarios for analysis, e.g. to determine a root cause of the failure. The root causes may be due to distinct modes of failure, such as traffic jams, road closures, deadlock conditions, or the like. Each class of interaction between the AV 102 and actor 104 near intersections 410 in the scene may be associated with distinct failure modes. The AV training system may rank or prioritize analysis of unsuccessful simulation scenarios based on the class of interaction so that subsequent analysis is more likely to include distinct failure modes, and less likely to include analyzing redundant failure modes. For example, the AV training system may prioritize one unsuccessful simulation scenario associated with each class of interaction above a second simulation scenario associated with any class of interaction.

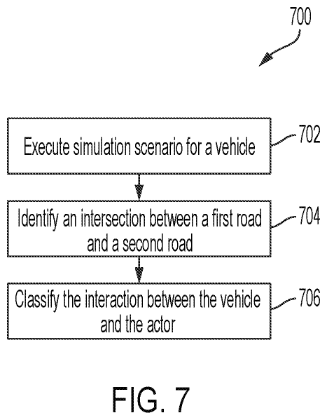

FIG. 7 shows an example method 700 for automatically classifying interactions in a simulation scenario. At step 702, the method 700 includes executing a simulation scenario that includes features of a scene through which a vehicle may travel, the simulation scenario including one or more actors 104. Features of the scene may include static objects, such as buildings and vegetation, and moving actors, such as other vehicles, bicycles, or pedestrians. Features may also include roads, lane markings, traffic control signs and/or signals. In some examples, the method 700 includes accessing simulation scenarios from a data store of a computing device. The data store may contain a variety of simulation scenarios. The data store may contain simulation scenarios created by engineers to train the AV 102.

These simulation scenarios may include a defined path of the AV 102 in the scenario. These simulation scenarios may include one or more actors 104 having defined characteristics, such as an initial position in the scene (e.g. a lane of a roadway occupied by the actor 104 in the scene). The scenario may include (or be associated with) geometric and semantic map information related to the scene, including roads and intersections 410. In some examples, simulation scenarios are time-stamped data previously recorded during a run of an AV 102, e.g., along a path on public roadways. These scenarios may include the position of the AV 102 along the path and data related to actors 104 perceived by the AV 102 during the run, including the position and the lane segment 402 occupied by the actors 104, as perceived by the AV 102.

At step 704, the method includes identifying an intersection between a first road and a second road in the scenario, wherein the intersection is in a planned path of the vehicle. As described above, engineers who create simulation scenarios (or a simulation-generating system) may define the planned path of the vehicle. The planned path may also be generated by a route-planning system based on a starting point of the vehicle a desired destination, and a map 400 of the scenario. The planned path may also be a recorded path of an AV 102 during a run in the real world. The method 700 may include executing simulation scenarios to determine actors 104 perceived by the AV 102 near intersections 410 along the planned path of the AV 102. In some examples, the method 700 includes analyzing logged or recorded data from a previously executed simulation or a real-world run of the AV 102 to determine actors 104 perceived by the AV 102 near intersections 410 along the planned path of the AV 102. The method 700 may include determining lane segments 402 occupied by the AV 102 and/or actors 104 entering and leaving intersections 410. And characteristics of the lane segments 402, such as neighboring lane segments 402, predecessor and successor lane segments 402, and direction of travel and turn semantics of the lane segments 402.

A set of roads may lead from the starting point to the desired destination along the planned path. As described above, the AV 102 may access a map 400 including geometric and semantic information of the roads along, and adjacent to, the planned path. The method 700 may include using semantic information to determine the lane segments that the AV 102 may occupy along the planned path. The method 700 may further include determining that the planned path includes one or more intersections 410. In some examples, the method 700 may include determining that the intersection 410 includes at least two roads, a first road that is in the planned path of the AV 102 and a second road that intersects the first road at the intersection 410. At step 706, the method 700 includes, in response to one of the actors 104 occupying a lane or lane segment 402 of either the first road or the second road, classifying the interaction between the AV 102 and the actor 104. In some examples, the classification is based on the configuration or other aspects of the intersection 410 (e.g., three-way, four-way, etc.), the path of the AV 102, and the lane segment 402 occupied by the actor 104.

The method 700 may include first determining that the actor 104 is near the intersection when the AV 102 is near the intersection, e.g. by determining that the AV 102 perceives the actor 104 and the intersection at the same moment in time, or by determining that the AV 102 and the actor 104 are both within a threshold distance (e.g., 30 meters) from the intersection 410 at the same moment in time, or by determining that the AV 102 and the actor 104 will enter the intersection 410 (or did enter the intersection 410, in the case of a previously recoded run) within a threshold period of time (e.g., 5 seconds), or that both the AV 102 and the actor 104 occupy lane segments whose successor is the intersection 410, etc. After determining that the actor 104 and the AV 102 are near the intersection 410, the method 700 may include classifying the interaction as (i) moving in the same direction, (ii) moving in opposing directions, (iii) actor 104 crossing from the left, or (iv) actor 104 crossing from the right. The method 700 may include classifying the interaction based on the lane semantics and geometry of the lane segment 402 occupied by the actor 104, or the lane semantics and geometry of a successor lane segment 402 occupied by the actor 104. For example, if the actor 104 occupies a single lane segment 402, the interaction can be classified by the successor lane segments 402 that are in intersection 410 between the AV 102 and actor 104. When both the AV 102 and actor 104 have a successor that has “going straight” semantics in the intersection 410, and the respective lane segments do not cross in the intersection, the interaction may be classified as “moving in the same direction” if these two successor lanes are have the same direction, and the interaction may be classified as “moving in the opposite direction” when the lane segments have different directions. The method 700 may include recursively finding neighboring lane segments 402 of the lane segment 402 occupied by the actor 104. The neighboring lane segments 402 may have the same direction as the lane segment 402 occupied by the actor 104 or may have the opposite direction.

If the actor 104 occupies two lane segments 402 in the intersection (or is predicted to occupy multiple lane segments in the intersection 410, e.g., based on successor lane segments) and if any of the lane segments 402 has a direction the same as the direction of the lane segment occupied by AV 102 in the intersection, the method 700 may classify the interaction as “moving in the same direction.” Alternatively, if none of the actor 104 lane segments 402 has a direction the same as the direction of the AV 102 lane segments, but one or more of the actor 104 lane segments 402 has a direction opposite to the direction of the AV 102 lane segments, the interaction may be classified as “moving in the opposite direction.” Otherwise, the interaction may be classified based on the location of the actor 104 and the geometry of the intersection 410, e.g., whether the lane segment 402 occupied by the actor 104 before the actor 104 enters the intersection 410 is to the right or to the left of the planned path of the AV 102.

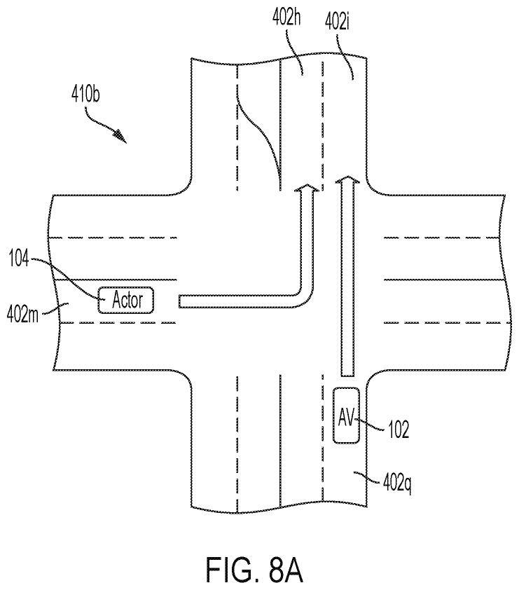

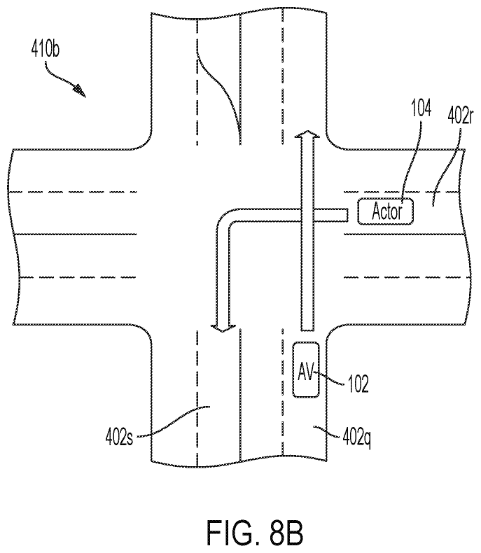

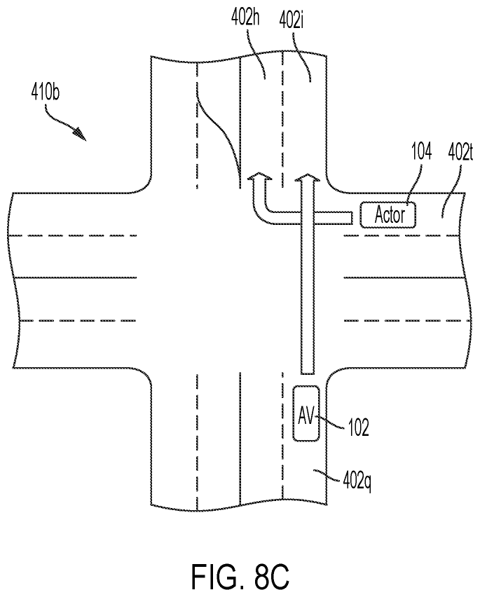

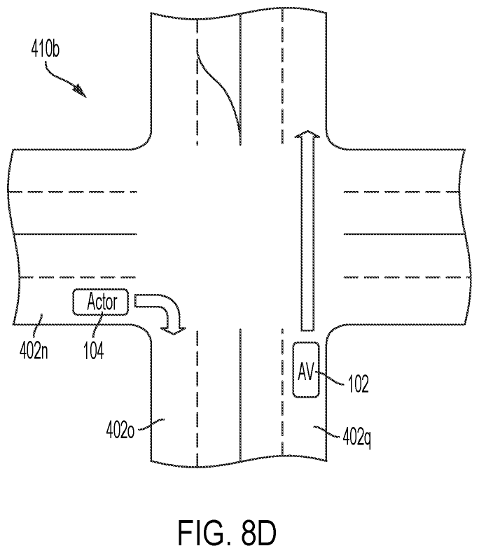

In some examples, the method 700 further includes classifying the interaction as “crossing from the left” or “crossing from the right” based on semantic information. For example, the method may include classifying the interaction based on (1) direction-change semantics of the lane segment 402 occupied by the actor 104 and (2) the lane segments 402 occupied by the AV 102 and the actor 104 as they enter or leave the intersection. The method may include recursively following successor lane segments 402 from a lane segment 402 currently occupied by the actor 104 or AV 102 to determine the lane segment 402 that will be occupied by the AV 102 and the actor 104 as they enter or leave the intersection 410. FIG. 8A shows example intersection 410b of FIG. 5. Here, AV 102 occupies lane segment 402q, and actor 104 occupies lane segment 402m. The planned path of AV 102 is straight across the intersection, proceeding onto lane segment 402i. Lane segment 402m, occupied by actor 104, may have left-turn semantics. Actor 104 turns left as it proceeds through the intersection 410b and onto lane segment 402h. The direction of the lane segment 402h occupied by the actor leaving the intersection is the same as the (neighboring) lane segment 402i occupied by the AV 102 leaving the intersection. The method 700 may include classifying the interaction as “crossing from the left” based on the left-turn semantics of the lane segment occupied by the actor 104, the planned path of the AV 102 straight through the intersection 410b, and the direction of the lane segments 402 occupied by the actor 104 and the AV 102 leaving the intersection. FIG. 8B shows actor 104 occupying lane segment 402r and turning left as the actor 104 proceeds through the intersection 410b and onto lane segment 402s. The direction of the lane segment 402s occupied by the actor leaving the intersection is opposite to the (neighboring lane) segment 402q occupied by the AV 102 entering the intersection. Otherwise, FIG. 8B is the same as FIG. 8A. Here, the method 700 may include classifying the interaction as “crossing from the right” based on the actor 104 turning left through the intersection, and the direction of the lane segment 402s occupied by the actor 104 leaving the intersection 410b being opposite to the direction of the lane segment 402q occupied by the AV 102 entering the intersection 410b, whether the AV 102 proceeds straight through the intersection 410b, turns left at the intersection, or turns right at the intersection.

FIG. 8C shows actor 104 occupying lane segment 402t and turning right as the actor 104 proceeds through the intersection 410b and onto lane segment 402h. Here, the method 700 may include classifying the interaction as “crossing from the right” based on the AV 102 proceeding straight through the intersection 410b, the actor 104 turning right at the intersection, and the direction of the lane segment 402h occupied by the actor 104 leaving the intersection 410b being the same as the direction of the (neighboring) lane segment 402i occupied by the AV 102 leaving the intersection 410b. FIG. 8D shows actor 104 occupying lane segment 402n and turning right as the actor 104 proceeds through the intersection 410b and onto lane segment 402s. Here, the method 700 may include classifying the interaction as “crossing from the left” based on the actor 104 turning right through the intersection and the direction of the lane segment 402o occupied by the AV 102 leaving the intersection 410b being opposite to the direction of the lane segment 402q occupied by the AV 102 entering the intersection 410b, whether the AV 102 proceeds straight through the intersection 410b, turns left at the intersection 410b, or turns right at the intersection.

Similarly, the method 700 may include classifying the interaction as “crossing from the right” based on the AV 102 turning right at the intersection, the direction of the lane segment 402 occupied by the AV 102 leaving the intersection 410b being opposite to the direction of the (neighboring) lane segment 402 occupied by the actor 104 entering the intersection 410b. And the method 700 may include classifying the interaction as “crossing from the left” based on the AV 102 turning left at the intersection, the direction of the lane segment 402 occupied by the AV 102 leaving the intersection 410b being opposite to the direction of the (neighboring) lane segment 402 occupied by the actor 104 entering the intersection 410b.

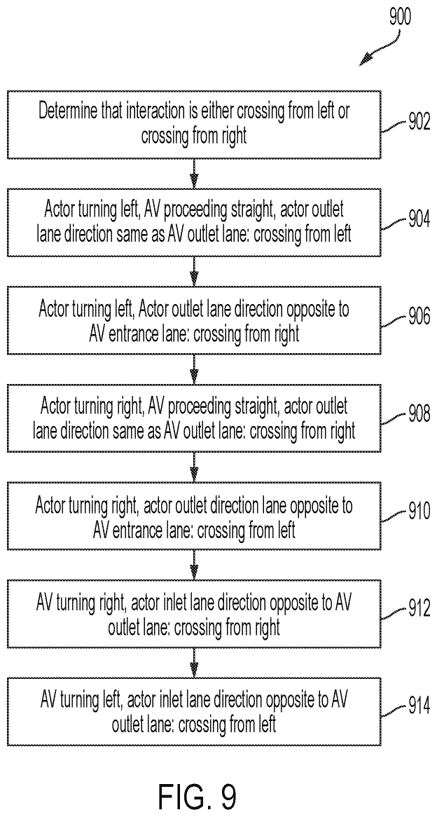

FIG. 9 shows a flowchart 900 of the classification method 700 described above. Step 902 of the flowchart 900 includes determining that the interaction is either “crossing from the left” or “crossing from the right.” As described above, if any lane occupied by the AV 102 has a direction either the same as or opposite to any lane occupied by the actor 102, then the interaction may be classified as “moving in the same direction” or “moving in the opposite direction.” And if both the AV 102 and the actor 104 proceed straight through the intersection 410, the interaction may be classified based on geometry of the intersection 410. In steps 902-914 of the flowchart 900, the classification is determined based on a direction change of the AV 102 and/or the actor 104, and the relative direction of lane segments 402 occupied by the AV 102 and actor 104 entering or leaving the intersection 410, as described above.

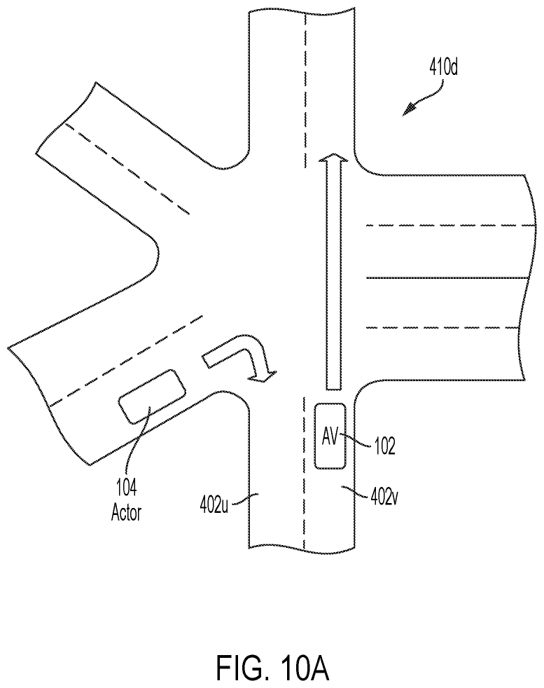

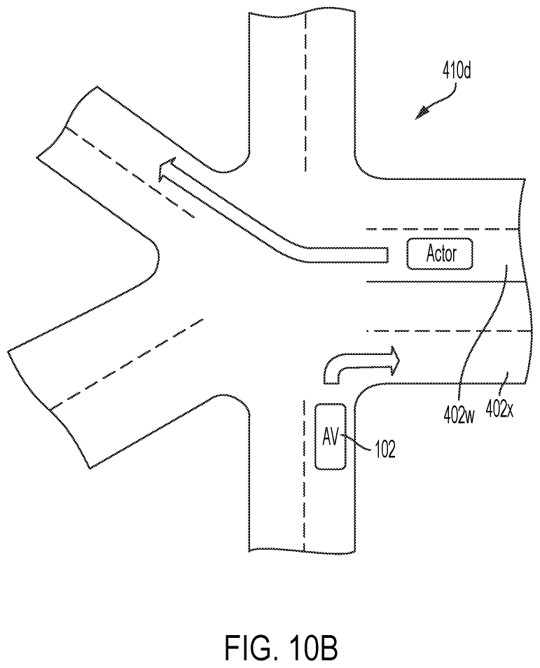

Although the example intersections shown are four-way intersections, aspects of the method 700 described above may be applied to more complex intersections, such as the five-way intersection shown in FIGS. 10A and 10B. Although lane segments 402 leading to or leaving from more complex intersections 410 may have a greater number of different directions, steps of the method 700 include comparing directions of neighboring lane segments 402 occupied by the AV 102 and the actor 104. Thus, interactions between the AV 102 and actors 104 may be classified even in highly complex of intersections, by determining whether the direction of neighboring lane segments 402 are the same or different. Referring to FIG. 10A, actor 104 turns right at the intersection 410d and proceeds onto lane segment 402u, and the AV 102 occupies lane segment 402v prior to entering the intersection 410d. The direction of lane segment 402v (the AV 102 inlet lane segment) is opposite to lane segment 402u (the actor 104 outlet lane segment). According to step 910 of the flowchart, the interaction is classified as “crossing from the left.” Referring to FIG. 10B, AV 102 turns right at the intersection 410d and proceeds onto lane segment 402x, and the actor 104 occupies lane segment 402w prior to entering the intersection 410d. The direction of lane segment 402w (the actor 104 inlet lane segment) is the same as lane segment 402x (the AV 102 outlet lane segment). According to step 912 of the flowchart, the interaction is classified as “crossing from the right.”

As described above, the AV training system may prioritize or rank simulation scenarios for inclusion in a training data set based on their associated classifications. In some examples, the method 700 includes executing many or all of the simulation scenarios store in the training system data store. In these examples, the method includes classifying the interactions between the AV 102 and one or more actors 104 near intersections 410 in the simulation scenario. The method may further include storing the classifications and the corresponding timestamps in a database or data store associated with the simulation scenario. The AV training system may prioritize or rank simulation scenarios for inclusion in a training data set based on the classifications associated with each simulation scenario. For example, the AV training system may prioritize scenarios having a large number of interactions, having interactions which are closely spaced in time or distance, or having a variety of classes of interactions. In some examples, the AV training system may prioritize scenarios having a particular class of interaction or scenarios having no interactions. By storing the classifications and corresponding timestamps in a database, the AV training system may prioritize or rank simulation scenarios in these and myriad other ways.

Various embodiments can be implemented, for example, using one or more computer systems, such as computer system 1100 shown in FIG. 11. Computer system 1100 can be any computer capable of performing the functions described herein.

Computer system 1100 can be any well-known computer capable of performing the functions described herein.

Computer system 1100 includes one or more processors (also called central processing units, or CPUs), such as a processor 1104. Processor 1104 is connected to a communication infrastructure or bus 1106.

One or more processors 1104 may each be a graphics processing unit (GPU). In an embodiment, a GPU is a processor that is a specialized electronic circuit designed to process mathematically intensive applications. The GPU may have a parallel structure that is efficient for parallel processing of large blocks of data, such as mathematically intensive data common to computer graphics applications, images, videos, etc.

Computer system 1100 also includes user input/output device(s) 1103, such as monitors, keyboards, pointing devices, etc., that communicate with communication infrastructure 1106 through user input/output interface(s) 1102.

Computer system 1100 also includes a main or primary memory 1108, such as random access memory (RAM). Main memory 1108 may include one or more levels of cache. Main memory 1108 has stored therein control logic (i.e., computer software) and/or data.

Computer system 1100 may also include one or more secondary storage devices or memory 1110. Secondary memory 1110 may include, for example, a hard disk drive 1112 and/or a removable storage device or drive 1114. Removable storage drive 1114 may be a floppy disk drive, a magnetic tape drive, a compact disk drive, an optical storage device, tape backup device, and/or any other storage device/drive.

Removable storage drive 1114 may interact with a removable storage unit 1118. Removable storage unit 1118 includes a computer usable or readable storage device having stored thereon computer software (control logic) and/or data. Removable storage unit 1118 may be a floppy disk, magnetic tape, compact disk, DVD, optical storage disk, and/any other computer data storage device. Removable storage drive 1114 reads from and/or writes to removable storage unit 1118 in a well-known manner.

According to an example embodiment, secondary memory 1110 may include other means, instrumentalities or other approaches for allowing computer programs and/or other instructions and/or data to be accessed by computer system 1100. Such means, instrumentalities or other approaches may include, for example, a removable storage unit 1122 and an interface 1120. Examples of the removable storage unit 1122 and the interface 1120 may include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface.

Computer system 1100 may further include a communication or network interface 1124. Communication interface 1124 enables computer system 1100 to communicate and interact with any combination of remote devices, remote networks, remote entities, etc. (individually and collectively referenced by reference number 1128). For example, communication interface 1124 may allow computer system 1100 to communicate with remote devices 1128 over communications path 1126, which may be wired and/or wireless, and which may include any combination of LANs, WANs, the Internet, etc. Control logic and/or data may be transmitted to and from computer system 1100 via communication path 1126.

In an embodiment, a tangible, non-transitory apparatus or article of manufacture comprising a tangible, non-transitory computer useable or readable medium having control logic (software) stored thereon is also referred to herein as a computer program product or program storage device. This includes, but is not limited to, computer system 1100, main memory 1108, secondary memory 1110, and removable storage units 1118 and 1122, as well as tangible articles of manufacture embodying any combination of the foregoing. Such control logic, when executed by one or more data processing devices (such as computer system 1100), causes such data processing devices to operate as described herein.

Based on the teachings contained in this disclosure, it will be apparent to persons skilled in the relevant art(s) how to make and use embodiments of this disclosure using data processing devices, computer systems and/or computer architectures other than that shown in FIG. X. In particular, embodiments can operate with software, hardware, and/or operating system implementations other than those described herein.

It is to be appreciated that the Detailed Description section, and not any other section, is intended to be used to interpret the claims. Other sections can set forth one or more but not all example embodiments as contemplated by the inventor(s), and thus, are not intended to limit this disclosure or the appended claims in any way.

Terminology that is relevant to the disclosure provided above includes:

An “automated device” or “robotic device” refers to an electronic device that includes a processor, programming instructions, and one or more physical hardware components that, in response to commands from the processor, can move with minimal or no human intervention. Through such movement, a robotic device may perform one or more automatic functions or function sets. Examples of such operations, functions or tasks may include, without limitation, operating wheels or propellers to effectuate driving, flying or other transportation actions, operating robotic lifts for loading, unloading, medical-related processes, construction-related processes, and/or the like. Example robotic devices may include, without limitation, autonomous vehicles, drones and other autonomous robotic devices.

The term “object,” when referring to an object that is detected by a vehicle perception system or simulated by a simulation system, is intended to encompass both stationary objects and moving (or potentially moving) actors, except where specifically stated otherwise by use of the term “actor” or “stationary object.”

When used in the context of autonomous vehicle motion planning, the term “trajectory” refers to the plan that the vehicle's motion planning system will generate, and which the vehicle's motion control system will follow when controlling the vehicle's motion. A trajectory includes the vehicle's planned position and orientation at multiple points in time over a time horizon, as well as the vehicle's planned steering wheel angle and angle rate over the same time horizon. An autonomous vehicle's motion control system will consume the trajectory and send commands to the vehicle's steering controller, brake controller, throttle controller and/or other motion control subsystem to move the vehicle along a planned path.

A “trajectory” of an actor that a vehicle's perception or prediction systems may generate refers to the predicted path that the actor will follow over a time horizon, along with the predicted speed of the actor and/or position of the actor along the path at various points along the time horizon.

In this document, the terms “street,” “lane,” “road” and “intersection” are illustrated by way of example with vehicles traveling on one or more roads. However, the embodiments are intended to include lanes and intersections in other locations, such as parking areas. In addition, for autonomous vehicles that are designed to be used indoors (such as automated picking devices in warehouses), a street may be a corridor of the warehouse and a lane may be a portion of the corridor. If the autonomous vehicle is a drone or other aircraft, the term “street” or “road” may represent an airway and a lane may be a portion of the airway. If the autonomous vehicle is a watercraft, then the term “street” or “road” may represent a waterway and a lane may be a portion of the waterway.

An “electronic device” or a “computing device” refers to a device that includes a processor and memory. Each device may have its own processor and/or memory, or the processor and/or memory may be shared with other devices as in a virtual machine or container arrangement. The memory will contain or receive programming instructions that, when executed by the processor, cause the electronic device to perform one or more operations according to the programming instructions.

The terms “memory,” “memory device,” “computer-readable medium,” “data store,” “data storage facility” and the like each refer to a non-transitory device on which computer-readable data, programming instructions or both are stored. Except where specifically stated otherwise, the terms “memory,” “memory device,” “computer-readable medium,” “data store,” “data storage facility” and the like are intended to include single device embodiments, embodiments in which multiple memory devices together or collectively store a set of data or instructions, as well as individual sectors within such devices. A computer program product is a memory device with programming instructions stored on it.

The terms “processor” and “processing device” refer to a hardware component of an electronic device that is configured to execute programming instructions, such as a microprocessor or other logical circuit. A processor and memory may be elements of a microcontroller, custom configurable integrated circuit, programmable system-on-a-chip, or other electronic device that can be programmed to perform various functions. Except where specifically stated otherwise, the singular term “processor” or “processing device” is intended to include both single-processing device embodiments and embodiments in which multiple processing devices together or collectively perform a process.

A “machine learning model” or a “model” refers to a set of algorithmic routines and parameters that can predict an output(s) of a real-world process (e.g., prediction of an object trajectory, a diagnosis or treatment of a patient, a suitable recommendation based on a user search query, etc.) based on a set of input features, without being explicitly programmed. A structure of the software routines (e.g., number of subroutines and relation between them) and/or the values of the parameters can be determined in a training process, which can use actual results of the real-world process that is being modeled. Such systems or models are understood to be necessarily rooted in computer technology, and in fact, cannot be implemented or even exist in the absence of computing technology. While machine learning systems utilize various types of statistical analyses, machine learning systems are distinguished from statistical analyses by virtue of the ability to learn without explicit programming and being rooted in computer technology.

A typical machine learning pipeline may include building a machine learning model from a sample dataset (referred to as a “training set”), evaluating the model against one or more additional sample datasets (referred to as a “validation set” and/or a “test set”) to decide whether to keep the model and to benchmark how good the model is, and using the model in “production” to make predictions or decisions against live input data captured by an application service. The training set, the validation set, and/or the test set, as well as the machine learning model are often difficult to obtain and should be kept confidential. The current disclosure describes systems and methods for providing a secure machine learning pipeline that preserves the privacy and integrity of datasets as well as machine learning models.

In this document, when relative terms of order such as “first” and “second” are used to modify a noun, such use is simply intended to distinguish one item from another, and is not intended to require a sequential order unless specifically stated.

In addition, terms of relative position such as “front” and “rear”, or “ahead” and “behind”, when used, are intended to be relative to each other and need not be absolute, and only refer to one possible position of the device associated with those terms depending on the device's orientation.

While this disclosure describes example embodiments for example fields and applications, it should be understood that the disclosure is not limited thereto. Other embodiments and modifications thereto are possible and are within the scope and spirit of this disclosure. For example, and without limiting the generality of this paragraph, embodiments are not limited to the software, hardware, firmware, and/or entities illustrated in the figures and/or described herein. Further, embodiments (whether or not explicitly described herein) have significant utility to fields and applications beyond the examples described herein.

Embodiments have been described herein with the aid of functional building blocks illustrating the implementation of specified functions and relationships thereof. The boundaries of these functional building blocks have been arbitrarily defined herein for the convenience of the description. Alternate boundaries can be defined as long as the specified functions and relationships (or equivalents thereof) are appropriately performed. Also, alternative embodiments can perform functional blocks, steps, operations, methods, etc. using orderings different than those described herein.

References herein to “one embodiment,” “an embodiment,” “an example embodiment,” or similar phrases, indicate that the embodiment described can include a particular feature, structure, or characteristic, but every embodiment can not necessarily include the particular feature, structure, or characteristic. Moreover, such phrases are not necessarily referring to the same embodiment. Further, when a particular feature, structure, or characteristic is described in connection with an embodiment, it would be within the knowledge of persons skilled in the relevant art(s) to incorporate such feature, structure, or characteristic into other embodiments whether or not explicitly mentioned or described herein. Additionally, some embodiments can be described using the expression “coupled” and “connected” along with their derivatives. These terms are not necessarily intended as synonyms for each other. For example, some embodiments can be described using the terms “connected” and/or “coupled” to indicate that two or more elements are in direct physical or electrical contact with each other. The term “coupled,” however, can also mean that two or more elements are not in direct contact with each other, but yet still co-operate or interact with each other.

The breadth and scope of this disclosure should not be limited by any of the above-described example embodiments but should be defined only in accordance with the following claims and their equivalents.

What is claimed is:

1. A method of automatically classifying interactions in a simulation scenario, the method comprising, by a processor:
executing a simulation scenario that includes features of a scene through which a vehicle may travel, the simulation scenario including one or more actors;
identifying an intersection between a first road and a second road in the simulation scenario, wherein the intersection is in a planned path of the vehicle; and
in response to one of the actors occupying a lane of either the first road or the second road, classifying the interaction between the vehicle and the actor into one or more classifications based on the intersection, the path of the vehicle, and the lane occupied by the actor.

2. The method of claim 1, wherein the one or more classifications comprise (i) moving in the same direction, (ii) moving in opposing directions, (iii) actor crossing from the left, or (iv) actor crossing from the right.

3. The method of claim 1, further comprising:
executing a plurality of additional simulation scenarios from a data store;
for each simulation scenario, classifying one or more interactions between the vehicle and one or more actors; and
ranking the simulation scenarios based on the one or more classifications.

4. The method of claim 1, wherein classifying the interaction comprises:
in response to the vehicle entering the intersection from a first lane segment of the first road and one of the actors entering the intersection from a second lane segment of the second road, classifying the interaction based on the planned path of the vehicle and a direction of the second lane segment.

5. The method of claim 1, wherein classifying the interaction comprises:
in response to one of the actors leaving the intersection on an exit lane segment, classifying the interaction based on the planned path of the vehicle and a direction of the exit lane segment.

6. The method of claim 1, further comprising:
classifying a plurality of interactions between the vehicle and the one or more actors in the simulation scenario, wherein each classification comprises one or more corresponding timestamps; and
storing the classifications and the corresponding timestamps in a data store associated with the simulation scenario.

7. The method of claim 6, wherein:
the simulation scenario comprises semantic information; and
the classification is based on direction-change semantics of one or more lane segments occupied by the vehicle or the actor in the intersection.

8. A system, comprising:
a processor;
a data store containing a plurality of simulation scenarios; and
a non-transient memory that stores programming instructions that are configured to cause the processor to:
execute a simulation scenario that includes features of a scene through which a vehicle may travel, the simulation scenario including one or more actors;
identify an intersection between a first road and a second road in the simulation scenario, wherein the intersection is in a planned path of the vehicle; and
in response to one of the actors occupying a lane of either the first road or the second road, classify the interaction between the vehicle and the actor into one or more classifications based on the intersection, the path of the vehicle, and the lane occupied by the actor.

9. The system of claim 8, wherein the one or more classifications comprise (i) moving in the same direction, (ii) moving in opposing directions, (iii) actor crossing from the left, or (iv) actor crossing from the right.

10. The system of claim 8, wherein the programming instructions are further configured to cause the processor to:
execute a plurality of additional simulation scenarios from the data store;
for each simulation scenario, classify one or more interactions between the vehicle and one or more actors; and
rank the simulation scenarios based on the one or more classifications.

11. The system of claim 8, wherein the programming instructions configured to cause the processor to classify the interaction comprise programming instructions configured to cause the processor to:
in response to the vehicle entering the intersection from a first lane segment of the first road and one of the actors entering the intersection from a second lane segment of the second road, classify the interaction based on the planned path of the vehicle and a direction of the second lane segment.

12. The system of claim 8, wherein the programming instructions configured to cause the processor to classify the interaction comprise programming instructions configured to cause the processor to:
in response to one of the actors leaving the intersection on an exit lane segment, classify the interaction based on the planned path of the vehicle and a direction of the exit lane segment.

13. The system of claim 8, wherein the programming instructions are further configured to cause the processor to:
classify a plurality of interactions between the vehicle and the one or more actors in the simulation scenario, wherein each classification comprises one or more corresponding timestamps; and
store the classifications and the corresponding timestamps in a data store associated with the simulation scenario.

14. The system of claim 13, wherein:
the simulation scenario comprises semantic information; and
the classification is based on direction-change semantics of one or more lane segments occupied by the vehicle or the actor in the intersection.

15. A computer program product comprising:
a memory that stores programming instructions that are configured to cause a processor to classify interactions in a simulation scenario by:
executing a simulation scenario that includes features of a scene through which a vehicle may travel, the simulation scenario including one or more actors;
identifying an intersection between a first road and a second road in the simulation scenario, wherein the intersection is in a planned path of the vehicle; and
in response to one of the actors occupying a lane of either the first road or the second road, classifying the interaction between the vehicle and the actor into one or more classifications based on the intersection, the path of the vehicle, and the lane occupied by the actor.

16. The computer program product of claim 15, wherein the one or more classifications comprise (i) moving in the same direction, (ii) moving in opposing directions, (iii) actor crossing from the left, or (iv) actor crossing from the right.

17. The computer program product of claim 15, wherein the programming instructions are further configured to cause the processor to classify interactions by:
executing a plurality of additional simulation scenarios from a data store;
for each simulation scenario, classifying one or more interactions between the vehicle and one or more actors; and
ranking the simulation scenarios based on the one or more classifications.

18. The computer program product of claim 15, wherein classifying the interaction comprises:
in response to the vehicle entering the intersection from a first lane segment of the first road and one of the actors entering the intersection from a second lane segment of the second road, classifying the interaction based on the planned path of the vehicle and a direction of the second lane segment.

19. The computer program product of claim 15, wherein classifying the interaction comprises:
in response to one of the actors leaving the intersection on an exit lane segment, classifying the interaction based on the planned path of the vehicle and a direction of the exit lane segment.

20. The computer program product of claim 15, wherein classifying the interaction comprises:
classifying a plurality of interactions between the vehicle and the one or more actors in the simulation scenario, wherein each classification comprises one or more corresponding timestamps; and
storing the classifications and the corresponding timestamps in a data store associated with the simulation scenario.
